(19) United States
(12) Patent Application Publication
(10) Pub. No.: US 2009/0067957 A1
(43) Pub. Date: Mar. 12, 2009

(54) TRANSPORT SYSTEM WITH BUFFERING

(76) Inventor: Mitsuhiro Ando, Ise (JP)

Correspondence Address: MARTINE PENILLA & GENCARELLA, LLP, 710 LAKEWAY DRIVE, SUITE 200, SUNNYVALE, CA, 94085, US

(21) Appl. No.: 12/205,606

(22) Filed: Sep. 5, 2008

Related U.S. Application Data
(60) Provisional application No. 60/970,526, filed on Sep. 6, 2007.

(51) Int. Cl. H01L 21/677

(52) U.S. Cl. 414/222.05; 414/806

(57) ABSTRACT

A workflow cell for a fabrication facility is provided. The workflow cell includes a semiconductor processing tool and a buffering station holding Front Opening Unified Pods (FOUPs) proximate to the semiconductor processing tool. The buffering station receives the FOUPs from a main stocker of the fabrication facility. The buffering station is configured to store a portion of the FOUPs in the main stocker. The workflow cell also includes a conveying mechanism connecting the semiconductor processing tool and the buffering station. In one embodiment, the conveying mechanism is the Direct Tool Load mechanism. A fabrication facility having the workflow and a method for moving a transport container are also provided.

### CLAIM OF PRIORITY

The present application claims priority under 35 U.S.C. § 119(e) from U.S. Provisional Patent Application No. 60/970,526, filed Sep. 6, 2007, which is incorporated by reference in its entirety for all purposes.

### BACKGROUND

It is costly to deliver containers such as front opening unified pods (FOUPs) and standard mechanical interface (SMIF) pods, to processing tools and load ports in a semiconductor fabrication facility. One method of delivering FOUPs and SMIF pods between processing tools is an automated material handling system (AMHS). An AMHS or transport system moves containers or cassettes of semiconductor wafers or flat panels in a fabrication facility. Container movement within the fabrication facility may be within each tool bay and/or between tool bays. Fabrication facilities often include stockers for storing containers. It is desirable to decrease delays in AMHS traffic by delivering containers directly from processing tool to processing tool as much as possible. Inadequate throughput capability in any part of the AMHS may cause other parts of the AMHS to have throughput that is below potential because of the inadequate component being serially linked to other parts. Containers are often delivered to a stocker after a process step is completed and then later removed and delivered to another tool when the tool is ready. The limited throughput of a conventional stocker limits the entire throughput capacity of the systems that deliver and remove containers from a stocker. Thus, the overall throughput capacity of the AMHS is limited to the stocker throughput. The assignee manufactures various high throughput systems, including a direct tool loading system disclosed in U.S. patent application Ser. No. 11/064,880, entitled “Direct Loading Tool”. The direct tool loading system may also create a throughput mismatch with conventional stockers. As described in the referenced U.S. Patent Application, the direct tool loading system is a floor-based container transport system (e.g., a container transport system that transports a container at an elevation equal to or lower than the processing tool loading height). The combination of very high throughput stockers and vertical container transport systems are required to fully utilize the throughput potential of the direct load system. Conventional stocker limitations may not be readily apparent in some AMHS because of the AMHS itself also has a limited throughput.

One type of AMHS or transport system is an overhead transport (OHT) system. In a conventional OHT system, an OHT vehicle, among other things, lowers an FOUP onto the kinematic plate of the load port at approximately 900 millimeter in height from the fabrication facility floor. An OHT system uses sophisticated ceiling mounted tracks and cable hoist vehicles to deliver FOUPs to these load ports. The combination of horizontal moves, cable hoist extensions, and unidirectional operation, must be coordinated for transporting FOUPs quickly between processing tools. For optimum efficiency within an OHT system an OHT vehicle must be available at the instant when a processing tool needs to be loaded or unloaded. The assignee's direct tool loading system provides an AMHS solution for high throughput intra-bay tool delivery capability. The direct tool loading system provides several advantages for throughput, such as, extension of high throughput conveyor AMHS directly to the tool, and, due to individual load port conveyor load/unload mechanisms, highly parallel conveyor interfaces. At any given time, many containers may be in the process of being dropped off onto the conveyor, or picked up from the conveyor with no mutual interference. To fully utilize its throughput potential, the AMHS requires a combination of high throughput stockers and vertical transport systems that efficiently connects to the interbay AMHS in flexible configurations that meet varying fab configurations.

Therefore, there is a need for improved high throughput container transport systems and storage capabilities within a fabrication facility.

### SUMMARY

Broadly speaking, the present invention fills these needs by providing an architecture for a transport system within a fabrication facility. It should be appreciated that the present invention can be implemented in numerous ways, including as a method, a system, or an apparatus. Several inventive embodiments of the present invention are described below.

In one embodiment, a workflow cell for a fabrication facility is provided. The workflow cell includes a semiconductor processing tool and a buffering station holding Front Opening Unified Pods (FOUPs) proximate to the semiconductor processing tool. The buffering station receives the FOUPs from a main stocker of the fabrication facility. The buffering station is configured to store a portion of the FOUPs in the main stocker. The workflow cell also includes a conveying mechanism connecting the semiconductor processing tool and the buffering station. In one embodiment, the conveying mechanism is the Direct Tool Load mechanism. A fabrication facility having the workflow is also provided.

In another embodiment, a method for moving transport containers in a semiconductor processing facility is provided. The method includes transporting the transport containers to buffering stations located proximate to processing tools under direction of a first control system. The buffering stations are part of respective workflow cells. The method includes moving the transport containers through the buffering stations and the respective workflow cells according to corresponding second control systems independent of the first control system. The moving includes aligning the transport container for a processing tool of the respective workflow cells in the buffering stations. The transport container is delivered to the processing tool through a floor based conveying mechanism, wherein a delivery port of the transport containers into the buffering stations and a delivery port of the transport containers to the conveying mechanism are aligned along a plane extending in front of the processing tool.

Other aspects and advantages of the invention will become apparent from the following detailed description, taken in conjunction with the accompanying drawings, illustrating by way of example the principles of the invention.

### BRIEF DESCRIPTION OF THE DRAWINGS

Aspects of the present invention will become apparent from the following detailed descriptions taken in conjunction with the accompanying drawings, illustrating by way of example the principles of the invention.

FIGS. 1 through 3 illustrate an exemplary embodiment of the direct tool loading apparatus in accordance with one embodiment of the invention.

FIG. 4 is a simplified schematic diagram illustrating a mini-stocker incorporated into the fabrication architecture in accordance with one embodiment of the invention.

FIG. 5 is a simplified schematic diagram illustrating a mini stocker used in conjunction with a sorter in one embodiment of the invention.

FIG. 6 is a simplified schematic diagram illustrating the placement of the mini stockers between tools in one embodiment of the invention.

FIG. 7 is a simplified schematic diagram illustrating a plurality of the mini stockers adjacent to each other for the use of storage in accordance with one embodiment of the invention.

FIG. 8 is a simplified schematic diagram illustrating further details of the mini stocker in accordance with one embodiment of the invention.

FIG. 9 illustrates a top view of the mini stocker of FIG. 8 in accordance with one embodiment of the invention.

FIG. 10 is a simplified schematic diagram illustrating the placement of the mini stocker between tools in accordance with one embodiment of the invention.

FIG. 11 is a simplified schematic diagram of a modular mini stocker that is moveable in one embodiment of the invention.

FIG. 12 is a simplified schematic diagram illustrating a design layout utilizing the mini stockers described herein in accordance with one embodiment of the invention.

### DETAILED DESCRIPTION

An invention is described for a workflow cell for handling semiconductor substrates involved in semiconductor manufacturing operations. It will be obvious, however, to one skilled in the art, that the present invention may be practiced without some or all of these specific details. In other instances, well known process operations have not been described in detail in order not to unnecessarily obscure the present invention.

The embodiments described herein provide for a system that provides a workflow cell for a semiconductor fabrication facility where a mini stocker or buffering station is provided to more efficiently move workpieces, such as semiconductor substrates, through the production facility. In one embodiment, a mini stocker having buffering capacity is placed in close proximity to a tool that performs a processing operation on the workpieces. With respect to semiconductor manufacturing, the workpieces may be semiconductor substrates that are stored in Front Opening Unified Pods (FOUPs). The FOUPs are transported between the mini stocker and the processing tool, through a conveying mechanism, such as the Direct Tool load mechanism. The Direct Tool load mechanism is further described in U.S. Pat. No. 7,410,340, which is incorporated herein by reference in its entirety for all purposes. As explained below, the mini stocker can orient the FOUPs in the correct orientation for delivery to the processing tool. In addition, the mini stocker can be serviced in place and is aligned with the processing tool to enable transport of the FOUPs over a conveyor, such as a Direct Tool Loading mechanism. In one embodiment, the work flow cell includes material transport functionality that operates in conjunction with the material handling system for the fabrication facility to efficiently move material.

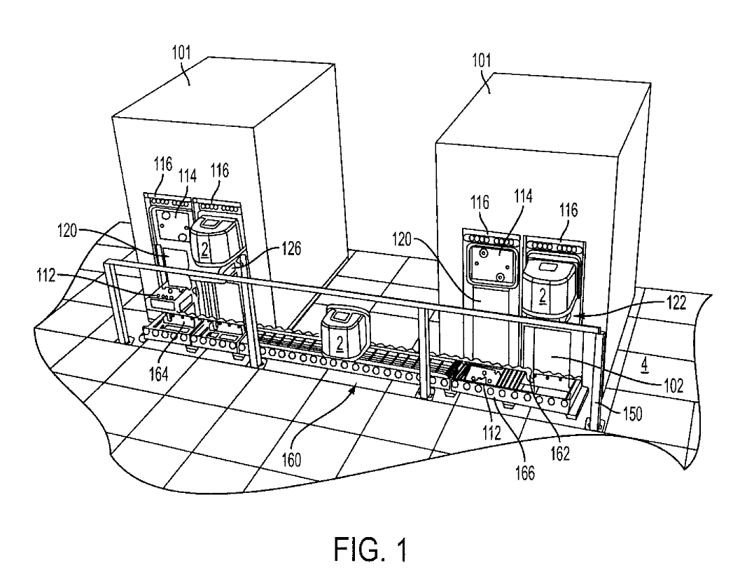

FIGS. 1 through 3 illustrate an exemplary embodiment of the direct tool loading apparatus in accordance with one embodiment of the invention. FIGS. 1-3 illustrate one embodiment of the present invention, which comprises a floor mounted conveyor 160 and a load port 100 having a vertically movable FOUP advance plate assembly 122. The conveyor 160 and load port 100 do not extend outward from the tool 101 any further than the conventional load port 10 extended outward from the tool by itself (e.g., X2). It is within the scope of the invention for the conveyor 160 to extend outward from the tool 101 further than the FOUP advance plate assembly 122. The term “conveyor” means an apparatus that conveys, such as a mechanical apparatus that transports materials, packages, or items from one place to another. By way of example only, the articles may be moved along the conveyor 160 by rollers, air track, railway, belt(s) or any other means known within the art.

The load port 100 includes, among other things, a kinematic plate 112, a port door 114, a mounting plate 116 and a FOUP advance plate assembly 122. The mounting plate 116 preferably secures to a tool 101 through either a BOLTS Interface or the proposed SEMI BOLTS-Light Interface (discussed later in application) and has an opening. The kinematic plate 112 preferably includes three kinematic pins 118 and an active container hold down mechanism (in compliance with SEMI Standard E15.1). The port door 114 moves between an open and closed position. By way of example only, the port door 114 comprises a Front Opening Interface Mechanical Standard (FIMS) door assembly. In this embodiment, the FIMS door 114 includes a pair of vacuum cups 115 and a pair of latch keys 117. The latch keys 117 open and close the FOUP door. The vacuum cups 115 evacuate the area between the FOUP door and the port door when the two doors are coupled together. The FIMS door 114 is not limited to the example shown in FIG. 1 and may include other features. In addition, it is within the scope of the invention for the load port 100 to not have a port door 114.

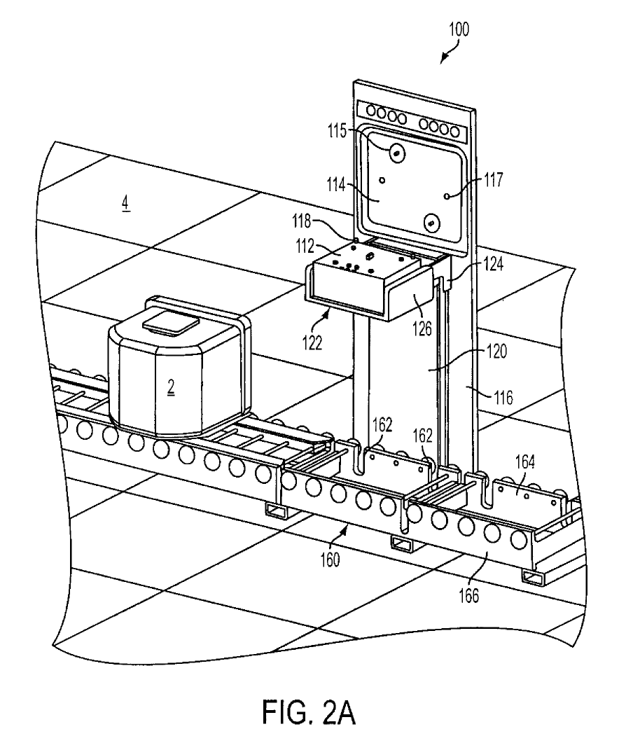

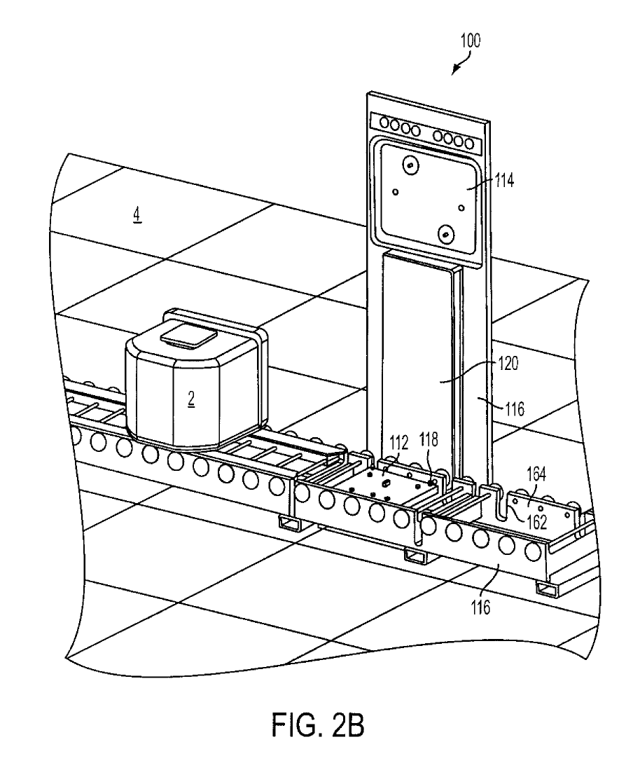

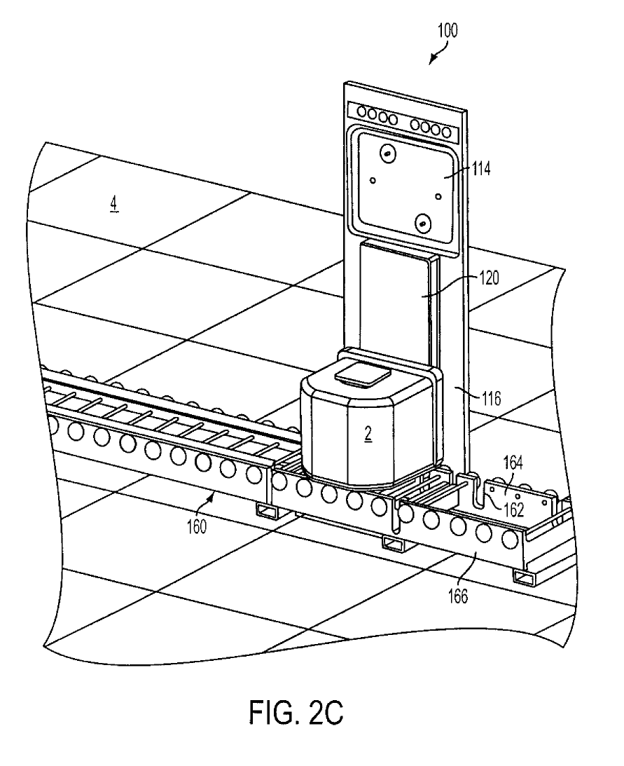

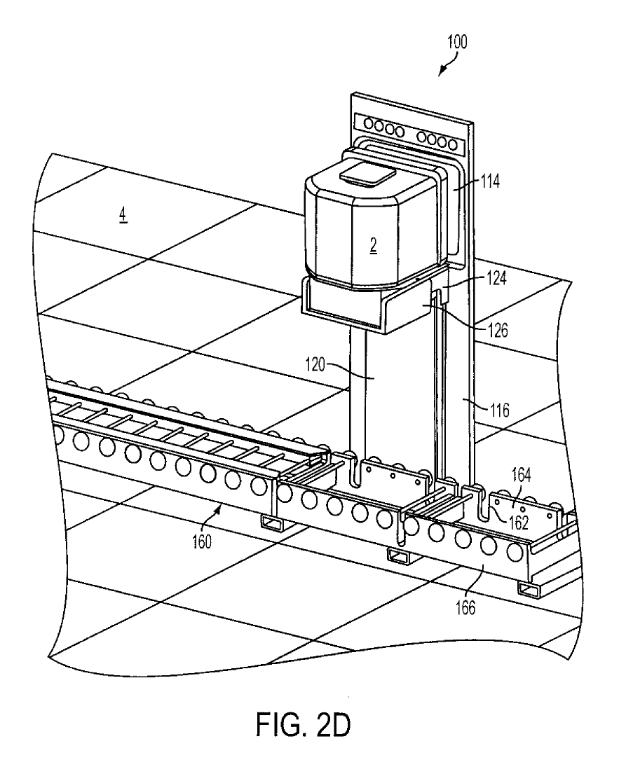

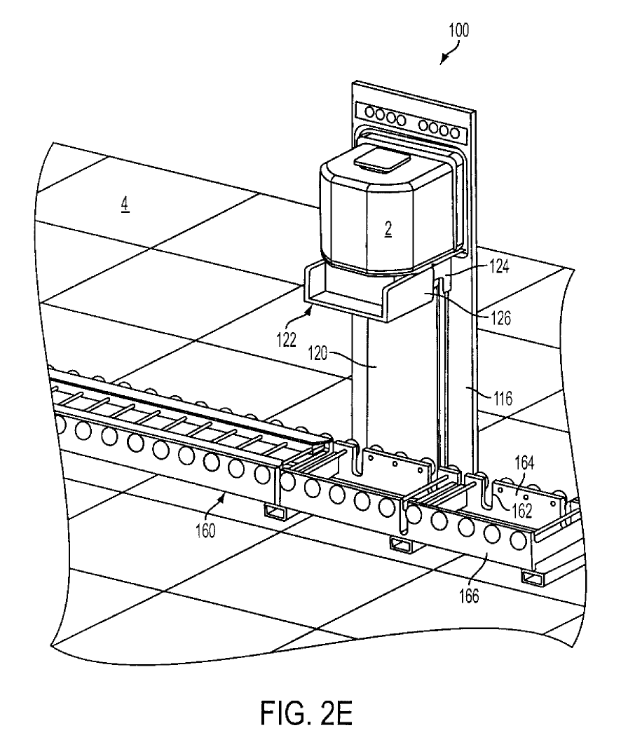

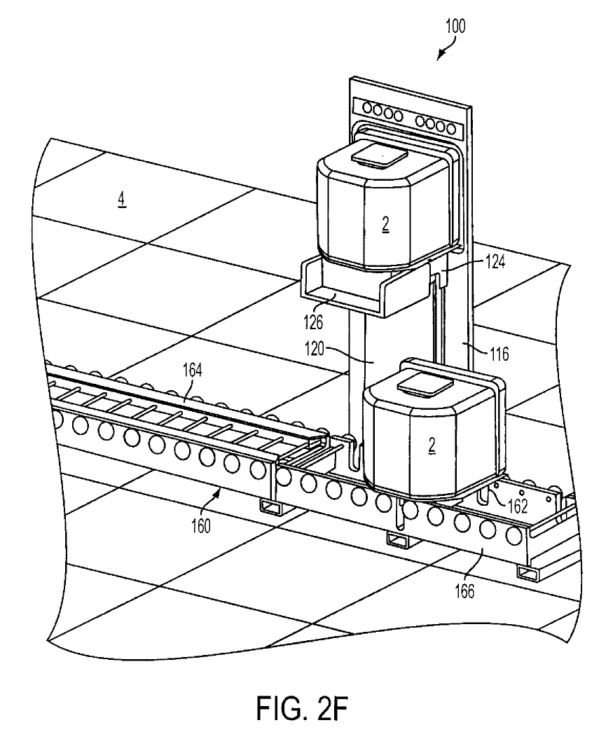

The FOUP advance plate assembly 122 includes a drive 126 for moving the kinematic plate 112 horizontally. The kinematic plate 112 supports the bottom surface of a FOUP and aligns the FOUP with respect to the opening in the mounting plate 116. The drive 126 moves the kinematic plate 112 between a first position (see FIGS. 2A-2D) and a second position (see FIGS. 2E-2F). In the first position, an OHT system may load or unload a FOUP 2 from the kinematic plate 112. The first position also places the kinematic plate 112 in a load/unload position for placing and removing a FOUP 2 from the conveyor or other transport device. The FOUP advance plate assembly 122 may move the kinematic plate 112 to the first position before the z-drive 120 lowers the FOUP advance plate 122 to the conveyor 160 or the kinematic plate 112 may move horizontally while the FOUP advance plate assembly 122 moves vertically.

It is also within the scope of the invention for the kinematic plate 112 to not move horizontally at all. For example, after the FOUP advance plate assembly 122 is raised vertically, the port door 114 may move horizontally towards the FOUP door to uncouple and remove the FOUP door. Or a port door may not be required at all if the container does not have a mechanically openable door. In this case, a container may be raised from the conveyor to a height where the tool can access the article.

FIG. 2A illustrates that, in one embodiment, a pair of supports 124 connect the FOUP advance plate assembly 122 to a z-drive mechanism 120. The present invention is not limited to the supports 124 shown in FIG. 2A. In fact, any support mechanism that connects the FOUP advance plate assembly 122 to the z-drive mechanism 120 will suffice. By way of example only, a single support may connect the FOUP advance plate assembly 122 to the z-drive mechanism 120. The supports 124 may be connected to the FOUP advance plate assembly 122 and the z-drive mechanism 120 by any structure known within the art. The z-drive mechanism 120 may comprise any drive assembly known within the art.

The load port 100 does not include a housing located below the FOUP advance plate assembly 122 similar to a conventional load port (e.g., housing 11 of load port 10). The area between the FOUP advance plate assembly 122 and the facility floor 4 is therefore cleared of obstructing components. In other words, the FOUP advance plate assembly 122 is able to move substantially vertically and parallel to the mounting plate 116. For purposes of describing the invention, the FOUP advance plate assembly 122 moves vertically between an uppermost height (see FIG. 2A) and a lowermost height (see FIG. 2B). The FOUP advance plate assembly 122 is able move to any position between these two heights. It is also within the scope of the invention for the FOUP advance plate assembly 122 to move between other heights (e.g., above the opening in the mounting plate 116).

To pick up a FOUP 2 off the conveyor 160, the FOUP advance plate assembly 122 is placed in the lowermost position. To do so, the z-drive mechanism 120 lowers the FOUP advance plate assembly 122 to the position is shown FIG. 2B. The FOUP advance plate assembly 122, while located in the lowermost position, is preferably situated between the first rail 164 and the second rail 166 of the conveyor 160. The FOUP advance plate assembly 122 must be lowered enough so that a FOUP 2 traveling along the conveyor 160 may pass unobstructed over the kinematic plate 112. In this embodiment, the kinematic plate 112 is moved to a forward position (away from port door) to fit between the rails 162, 164.

FIG. 2C illustrates a FOUP 2 that has come to a complete stop on the conveyor 160 over the kinematic plate 112. The FOUP 2 preferably comes to rest over the kinematic plate 112 when the kinematic pins 118 align with the pin receptacles on the bottom surface of the FOUP 2. While the FOUP 2 and kinematic plate 112 are aligned, z-drive 120 raises the FOUP advance plate assembly 122. The kinematic plate 112 eventually contacts the bottom surface of the FOUP 2 and lifts the FOUP 2 off the conveyor 160 as the z-drive 120 continues to raise the FOUP advance plate assembly 122 towards the uppermost position (see FIG. 2D). No further adjustment between the FOUP 2 and the kinematic plate 112 are necessary in order to access wafers in the FOUP.

The conveyor 160 shown in FIGS. 2A-2C transports the FOUP 2 so that the FOUP door faces the load port when the FOUP arrives at eh load port. It is within the scope and spirit of the invention to transport the FOUP along the conveyor in other orientations. By way of example only, the FOUP may travel along the conveyor with the FOUP door facing the direction the FOUP is moving. In this situation, the FOUP advance plate assembly 122, after it picks up a FOUP 2 from the conveyor 160, rotates the FOUP 2 ninety degrees so that the FOUP door faces the load port.

At this point, the FOUP advance plate assembly 122 moves the kinematic plate 112 towards the port door 114. The FOUP is moved forward until the port door is close enough to the FOUP door to uncouple and remove the FOUP door. By way of example only, a port door that is able to unlock and remove the FOUP door and transport the FOUP and port door within the tool is described in U.S. Pat. No. 6,419,438, entitled “FIMS Interface Without Alignment Pins,” which is assigned to Asyst Technologies, Inc., and is incorporated herein by reference. FIG. 2F illustrates that additional FOUPs in the fabrication facility travel unobstructed along the conveyor 160 to another processing tool while the wafers within the FOUP 2 located on the kinematic plate 112 are being processed.

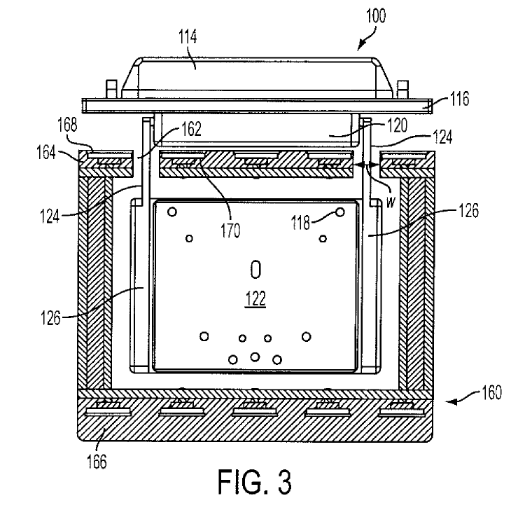

A FOUP 2 travels along the first and second rails 164, 166 of the conveyor 160. FIG. 3 illustrates that the rails are preferably spaced apart to accommodate the FOUP advance plate assembly 122 while located in the lowermost position, between the rails. In the FIGS. 1-3 embodiment, each section of the conveyor 160 located in front of the load port 100 includes two slots 162 in the first rail 164. Each slot 162 allows a support 124 to pass through the first rail 164 as the FOUP advance plate assembly 122 is lowered to the lowermost position (see FIG. 2B). The slots 162 allow the z-drive 120 to lower the kinematic plate 112 to a position where a FOUP 2 traveling along the conveyor 160 can pass over the kinematic plate unobstructed. Any modification to the first rail 164 that accommodates a support 124 is within the spirit and scope of this invention. Similarly, if the load port 100 only includes one support 124, the rail 164 only requires one slot 162.

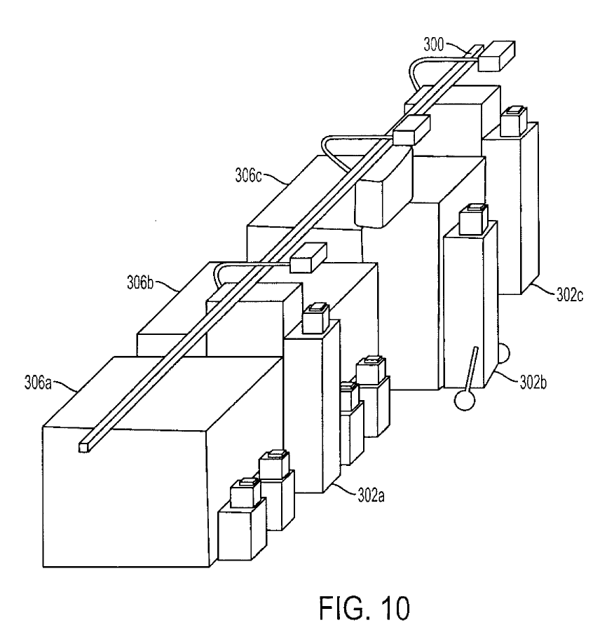

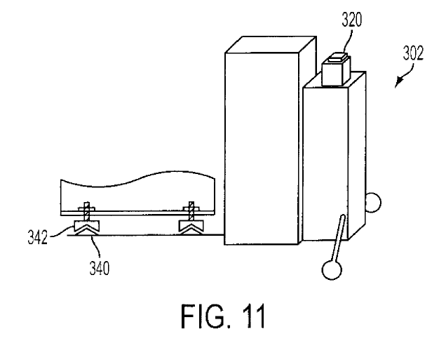

FIGS. 1-2 illustrate several features of a floor mounted conveyor 160. It is within the scope of the present invention to place the conveyor at any height within the fabrication facility. By way of example only, the conveyor 160 may be located below the facility floor 4 (e.g., FIG. 11), flush with the facility floor 4 (e.g., FIG. 10) or above the load port (not shown).

Regardless of the height of the conveyor system relative to the load port, each FOUP 2 preferably travels along the conveyor 160 such that the FOUP door 6, when the FOUP 2 arrives at the load port 100, faces the port door. However, a FOUP may travel along the conveyor in other orientations and can eventually be rotated to face the port door. Either way, the number of times each FOUP 2 is handled between the conveyor and the load port is greatly reduced. For example, after a FOUP is lifted off the conveyor by the FOUP advance plate assembly, the FOUP does not have to be aligned again prior to accessing the wafers. The FOUP is lifted off the conveyor and does not have to be handled by a robotic arm (e.g., required in an RGV system). The load port 100 eliminates this additional handling step, which provides faster transfer of FOUPs from a conveyor or other transport device to a load port and minimizes handling of the FOUP 2.

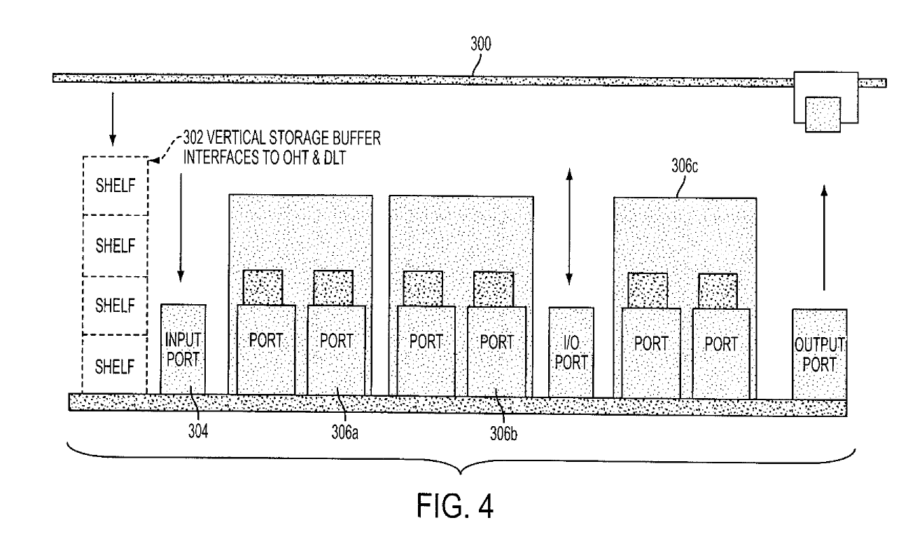

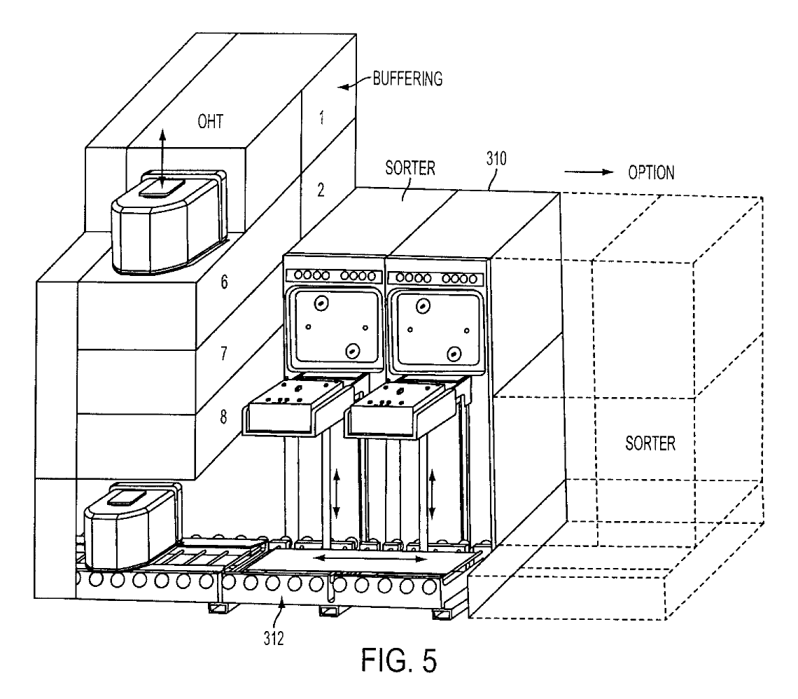

FIG. 4 is a simplified schematic diagram illustrating a mini-stocker incorporated into the fabrication architecture in accordance with one embodiment of the invention. OHT transport system 300 provides FOUPs to mini stocker 302 which in turn supplies the FOUPs to input ports 304, which can be distributed to tools 306a, 306b and 306c through a DTL conveyor. Mini stocker 302 will have a dedicated material handler 320 that will move FOUPs within the mini stocker in order to improve throughput, as illustrated in later Figures. In addition, mini stocker 302 can be serviced within its position in one embodiment. In another embodiment, mini stocker 302 can be moveable to provide for access as illustrated in later Figures. It should be appreciated that numerous mini stockers 302 may be distributed between tools in one embodiment of the invention. It should be appreciated that the mini stocker in combination with other tools, and the conveying mechanism providing the transport of the containers between the two, may be referred to as a work flow cell. The embodiment of FIG. 4 illustrates an AMHS delivering FOUPs to the mini stocker and the secondary transportation system of the work flow cell handles the movement of the FOUP within the work flow cell so as to alleviate that responsibility from the AMHS. In one embodiment, one mini-stocker may be used to receive FOUPs from the OHT transport system for subsequent delivery to a processing tool, while a second mini-stocker may be used to deliver FOUPs to the OHT transport system from the processing tool. Thus, there are separate inputs and outputs for the workflow cell. In this manner, the conveying mechanism may be unidirectional. It should be appreciated that this is not meant to be limiting as the mini-stocker and the conveying mechanism may be bi-directional as discussed with regard to FIG. 5.

Still referring to FIG. 4, one embodiment includes separate input and output ports as mentioned above. In this embodiment, the input and output ports may both be mini stockers or only one of the input and output ports may be a mini stocker. Furthermore, in one exemplary embodiment, mini stocker 302 services each of the processing tools 306a-c while the stations proximate to the processing tools, i.e., input port 304, the I/O port and the output port, would service only the adjacent processing tool. One skilled in the art will appreciate that numerous configurations are possible and input port 304, the I/O port and the output port are optional, as the output port can be replaced with a mini stocker in one embodiment. It should be noted that the containers are typically queued for input, however, this is not necessary for the output side. Thus, the mini stocker for the input side may have a larger capacity than a mini stocker for the output side in one embodiment.

FIG. 5 is a simplified schematic diagram illustrating a mini stocker used in conjunction with a sorter in one embodiment of the invention. As illustrated in FIG. 5, mini stocker 302 is adjacent to sorter 310, where FOUPs may be transferred between mini stocker 302 and sorter 310 by a floor-mounted conveyor 312. One skilled in the art will appreciate that the sorter may be any tool that is configured to handle wafers, read wafers, etc. In some applications, sorters may be configured to act in a high throughput system where only a relatively small portion of the wafers are checked by the sorter. The floor-mounted conveyor 312 may be the direct load tool (DLT) architecture owned by the assignee. One skilled in the art will appreciate that as the FOUPs come into mini stocker 302 and are distributed to sorter 310, the mini stocker assists in enhancing the throughput. It should be appreciated that mini stocker 302 provides FOUPs to sorter 310 more timely than a large storage unit typically employed in a fabrication facility. In one embodiment, the work flow cell defined by the mini stocker and the sorter may include a process tool adjacent to sorter 310. One skilled in the art will appreciate that the FOUPs are aligned for use in the processing tool and are not needed to be spun for use in the processing tool, as is required with the large storage units typically employed in the fabrication facility. That is, the FOUPs are oriented in the correct direction for tool loading. As will be appreciated by one skilled in the art, the large storage units that currently warehouse the FOUP's for eventual supply to a process tool are unable to orient the FOUPs correctly for tool loading, therefore, the FOUPs must be spun to the correct orientation at some point. In addition, OHT 300 is aligned so that access is enabled to mini stocker 302, sorter 310, and any other adjacent tools. This alignment enables multiple possibilities to pick up and drop off FOUPs to the mini stocker, which in turn enables quicker access to the FOUPs as compared to the turn around and access for FOUPs from a large storage unit. The multiple alternatives include drop off points to the mini stocker or any one of the sorter drop off points and/or the DLT conveyor on the bottom of the floor for input/output to or from the sorter or the stocker. Through the embodiments described herein, the control system for the fabrication facility can provide a command to move a FOUP to a mini stocker and the controller for the work flow cell can handle the movement within the work flow cell. This local control within the workflow cell enhances FOUP throughput. It should be appreciated that the local control within the work flow cell eliminates moves required by a fabrication facility's AMHS/OHT system. With the configuration described herein, the throughput time for a FOUP to be transferred between a stocker and a sorter is approximately 20 seconds as opposed to 4+ minutes that it may take the AMHS to supply a FOUP from a large storage facility typically used in the fabrication facility. Consequently, the amount of time that the stocker or sorter does not have FOUPs because of the 4+ minute access time is drastically reduced. Furthermore, the alignment of the DLT with the OHT enables the DLT to provide FOUPs in about 10% to 20% of time required by the OHT that is not aligned with the sorter, stocker and DLT conveyor. It should be further appreciated that mini stocker 302 includes a top located port that may act to receive FOUPs from OHT 300 and deliver FOUPs to OHT 300. In addition, floor mounted conveyor may be bidirectional, i.e., deliver FOUPs to the process tool from the bottom port of the mini stocker and return FOUPs to the bottom port of the mini stocker from the process tool. The movement of the FOUPs in the workflow cell can be controlled by a workflow controller independent of the AMHS or facility wide controller.

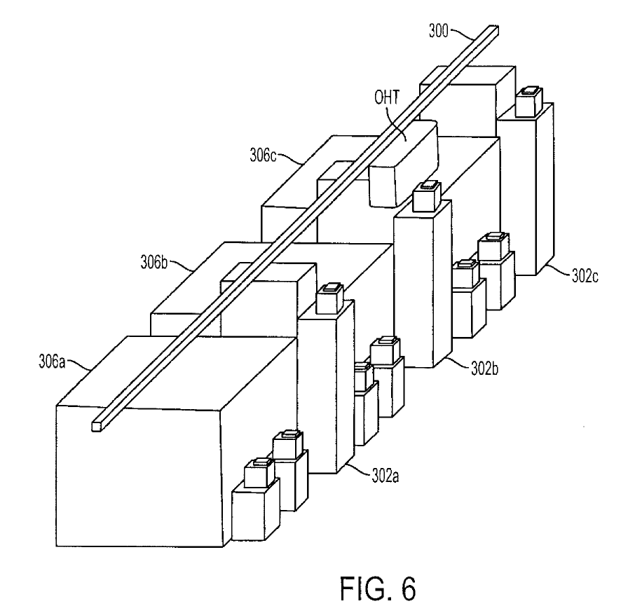

FIG. 6 is a simplified schematic diagram illustrating the placement of mini stockers 302 between tools in one embodiment of the invention. In this embodiment, mini stocker 302a through 302c are distributed adjacent to process tools 306a through 306c, respectively. In addition, there is a linear relationship between the handler for the mini stockers 302 and the loading/unloading mechanism for the process tool. Thus, OHT 300 is able to service both the mini stockers and the process tools.

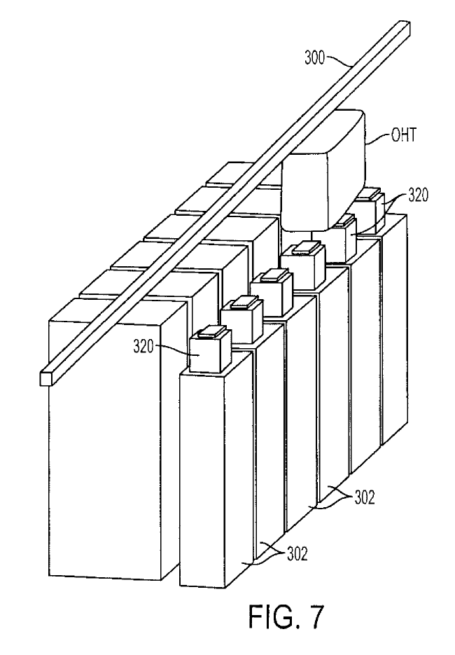

FIG. 7 is a simplified schematic diagram illustrating a plurality of mini stockers 302 adjacent to each other for the use of storage in accordance with one embodiment of the invention. In this embodiment, each mini stocker 302 is associated with a dedicated material handling system 320 in order to achiever a highly efficient system capable of outputting much more FOUPs per unit of time than the traditional stocker. One skilled in the art will appreciate that the material handling systems of FIGS. 6 and 7 are aligned with each other and with the OHT 300 and the material handling systems for the process tools in FIG. 6. Thus, this linear architecture is much more efficient and one OHT system can handle supply of both the mini stocker 302 and each of the process tools 306.

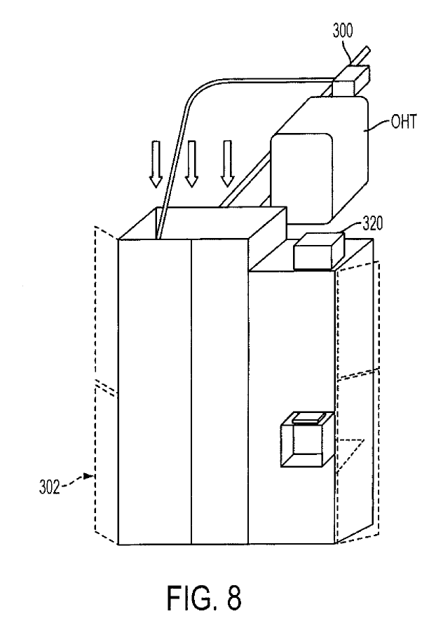

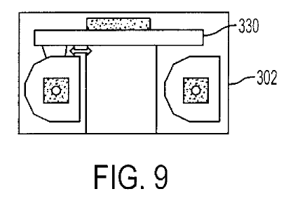

FIG. 8 is a simplified schematic diagram illustrating further details of mini stocker 302 in accordance with one embodiment of the invention. As illustrated in FIG. 8, a FOUP is supplied through OHT system 300 into mini stocker 302. Mini stocker 302 has multiple doors for servicing access. An up/down rail handles the movement of FOUP within the mini stocker. The top of the stocker is open as illustrated in FIG. 8. In one embodiment, mini stocker 302 has a vertical and horizontal axis to pick up and drop off containers as further described with reference to FIG. 9. Material handling system 320 interfaces with OHT 300 and an appropriate controller to transfer FOUPs accordingly.

FIG. 9 illustrates a top view of the mini stocker of FIG. 8 in accordance with one embodiment of the invention. As illustrated, the FOUPs rests on a two-axis stacker so that numerous FOUPs can be stored within the mini stocker. The two axes include a vertical axis that enables vertical movement of the FOUPs and a horizontal axis as depicted by the arrow within FIG. 9.

FIG. 10 is a simplified schematic diagram illustrating the placement of mini stocker 302 between tools in accordance with one embodiment of the invention. In FIG. 10 the mini stocker 302 is capable of being pulled out into an aisle way where servicing may be needed in the case where access between the tools are too tight. The linear nature of the alignment of the material handling systems for mini stockers 302, material handling systems for process tools 306 and OHT 300 enables a single OHT to accommodate the mini stockers and the process tools.

FIG. 11 is a simplified schematic diagram of a modular mini stocker that is moveable in one embodiment of the invention. Mini stocker 302 may include wheels enabling movement of the mini stocker. Mini stocker 302 may be positioned according to the mating of cups 342 and centering cones 340 in one embodiment. Of course, other known alignment techniques may be incorporated here.

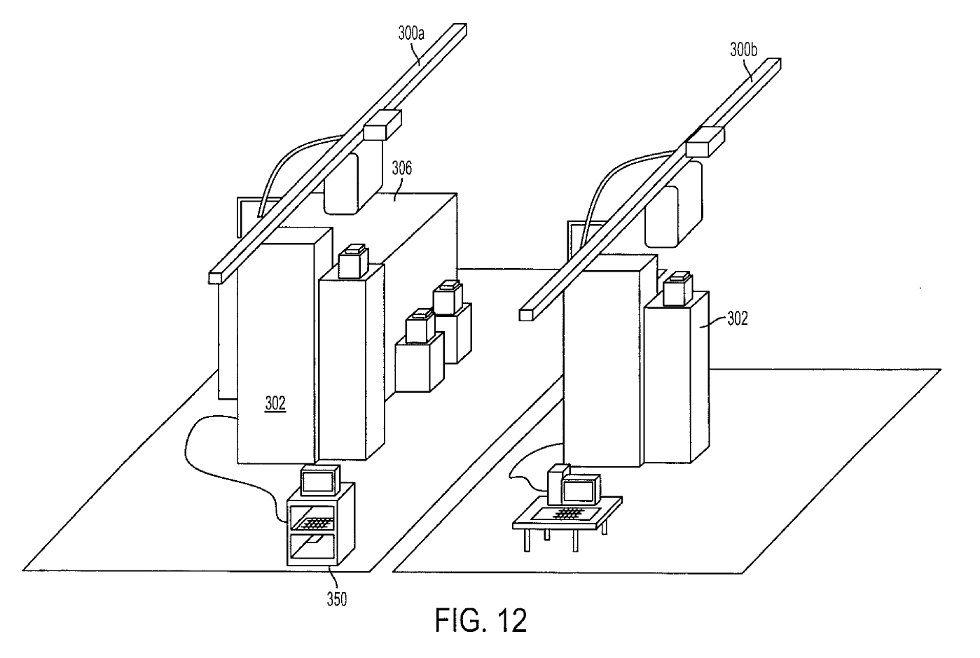

FIG. 12 is a simplified schematic diagram illustrating a design layout utilizing the mini stockers described herein in accordance with one embodiment of the invention. OHT 300a and 300b, which may eventually join through a common U-track section, have access to move FOUPs between mini stockers 302 and process tool 306. Controller 350 includes a processor and memory for executing code that may be used to control the transfer of the FOUPs. In summary, due to the modular nature of the workflow cells, the transfer of the FOUPs becomes more efficient. In addition, the mini stockers described herein can be shipped as an integral unit to a fabrication facility, rather than having to be installed at the facility, as is currently required with the large stockers. Furthermore, since each mini stocker includes a material handling system, the amount of FOUPs moved per unit time increases accordingly.

It should be appreciated that the above-described container and isolation systems are for explanatory purposes only and that the invention is not limited thereby. Having thus described a preferred embodiment of a container and system for storing, transporting and loading large area substrates or wafers, it should be apparent to those skilled in the art that certain advantages of the within system have been achieved. It should also be appreciated that various modifications, adaptations, and alternative embodiments thereof may be made within the scope and spirit of the present invention. For example, the container and system may also be used to store other types of substrates or be used in connection with other equipment within a semiconductor manufacturing facility. It should be appreciated that many of the inventive concepts described above would be equally applicable to the use of non-semiconductor manufacturing applications as well as semiconductor related manufacturing applications. Exemplary uses of the inventive concepts may be integrated into solar cell manufacturing and related manufacturing technologies, such as; single crystal silicon, polycrystalline silicon, thin film, and organic processes, etc.

Any of the operations described herein that form part of the invention are useful machine operations. The invention also relates to a device or an apparatus for performing these operations. The apparatus can be specially constructed for the required purpose, or the apparatus can be a general-purpose computer selectively activated, implemented, or configured by a computer program stored in the computer. In particular, various general-purpose machines can be used with computer programs written in accordance with the teachings herein, or it may be more convenient to construct a more specialized apparatus to perform the required operations.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims. In the claims, elements and/or steps do not imply any particular order of operation, unless explicitly stated in the claims.

1. A layout for a fabrication facility, comprising:
a semiconductor processing tool;
a buffering station holding Front Opening Unified Pods (FOUPs) proximate to the semiconductor processing tool, a top located port of the buffering station receiving the FOUPs from an overhead transport (OHT) mechanism; and
a conveying mechanism connecting a bottom port of the buffering station to a load port of the semiconductor processing tool.

2. The layout of claim 1, wherein the conveying mechanism is a Direct Load mechanism and the load port is a Direct Load load port.

3. The layout of claim 1, wherein the FOUPs are stored in a pre-aligned orientation for the processing tool thereby eliminating any orientation movement of the FOUPs outside of the buffering station.

4. The layout of claim 1, wherein the buffering station is configured to move the FOUPs along two axes.

5. The layout of claim 1, wherein the top located port of the buffering station is exposed to the OHT mechanism.

6. The layout of claim 1, wherein the top located port of the buffering station and the bottom port of the buffering station are aligned along a plane extending from the conveying mechanism.

7. The layout of claim 1, further comprising:
a control system for the fabrication facility for moving FOUPs to and from the buffering station; and
a workflow controller for handling movement of the FOUPs within a workflow cell defined by the buffering station, the processing tool, and the conveying mechanism.

8. The layout of claim 1, wherein the conveying mechanism is bi directional so as to deliver FOUPs to the bottom port from the processing tool in a first direction and pick up FOUPs from the bottom port for the processing tool in a second direction.

9. The layout of claim 1 wherein the buffering station stores a maximum of fifteen FOUPs.

10. The layout of claim 1, wherein the OHT mechanism drops off FOUPs and picks up FOUPs at the top located port.

11. The layout of claim 1, wherein the conveying mechanism is uni directional and the buffering station acts as an input port for the OHT mechanism to the processing tool and another buffering station acts as an output port for the OHT mechanism to the processing tool.

12. A semiconductor processing facility architecture, comprising;
a first control system controlling movement of transport containers throughout the facility;
a plurality of workflow cells, each of the workflow cells including,
a semiconductor processing tool;
a buffering station storing the transport containers proximate to the semiconductor processing tool, a top located port of the buffering station receiving the FOUPs from an overhead transport (OHT) mechanism; and
a conveying mechanism connecting a bottom port of the buffering station to a load port of the semiconductor processing tool; and
a second control system controlling movement of the transport container within the workflow cell independent of the first control system.

13. The facility architecture of claim 12, wherein the conveying mechanism is a Direct Load Tool mechanism.

14. The facility architecture of claim 12, wherein the transport containers are stored in a pre-aligned orientation for the processing tool thereby eliminating any orientation movement of the transport containers outside of the buffering station.

15. The facility architecture of claim 12, wherein the buffering station is configured to move the transport containers along two axes.

16. The facility architecture of claim 12, wherein the top located port is exposed to the OHT mechanism.

17. The facility architecture of claim 12, wherein the top located port of the buffering station and the bottom port of the buffering station are aligned along a plane extending from the conveying mechanism.

18. A method for moving transport containers in a semiconductor processing facility, comprising:
transporting the transport containers via and overhead transport mechanism to buffering stations located proximate to processing tools, the transporting performed under direction of a first control system, the buffering stations part of respective workflow cells, the workflow cells defined by one of the buffering stations, one of the processing tools and a conveying mechanism providing a transport path between the one of the buffering stations and the one of the processing tools;
moving the transport containers through the buffering stations and the respective workflow cells according to corresponding second control systems independent of the first control system, the moving including,
maintaining orientation of the transport container for a processing tool of the respective workflow cells in the buffering stations; and
delivering the transport container to the processing tool through a floor based conveying mechanism, wherein a delivery port of the transport containers into the buffering stations and a delivery port of the transport containers to the conveying mechanism are aligned along a plane extending in front of the processing tool.

19. The method of claim 18, further comprising;
delivering the transport containers to a top of the buffering stations; and
delivering the transport containers from the buffering stations to the conveying mechanism through a bottom of the buffering stations.

20. The method of claim 18, wherein the buffering stations store a maximum of fifteen FOUPs.

21. The method of claim 18, wherein the delivery port of the transport containers into the buffering stations and the delivery port of the transport containers to the conveying mechanism are bidirectional in that the transport containers are dropped off and picked up at each delivery port in opposing directions on the conveying mecahnism.
